(19) United States
(12) Patent Application Publication
(10) Pub. No.: US 2024/0170298 A1
(43) Pub. Date: May 23, 2024

(54) METHOD FOR PRODUCING AN INTEGRATED CIRCUIT TO REMEDY DEFECTS OR DISLOCATIONS

(71) Applicant: EM Microelectronic-Marin SA, Marin (CH)

(72) Inventors: Jean-Philippe JACQUEMIN, Doubs (FR); Jérôme LOLIVIER, Yverdon-les-bains (CH); René MEYER, Le Landeron (CH)

(73) Assignee: EM Microelectronic-Marin SA, Marin (CH)

(21) Appl. No.: 18/495,840

(22) Filed: Oct. 27, 2023

(30) Foreign Application Priority Data
Nov. 23, 2022 (EP) 22209151.4

(51) Int. Cl. H01L 21/3205; H01L 21/324

(52) U.S. Cl. CPC H01L 21/32053; H01L 21/324

(57) ABSTRACT

A method to produce an integrated circuit including depositing a first layer of a metallic chemical constituent on a silicon substrate. A protective layer including a main chemical constituent different from the main chemical constituent of the first layer is then deposited on this first layer. An additional layer is deposited on the protective layer and includes a main chemical constituent different from, equivalent to or of equivalent size to the main chemical constituent of the first layer. A heat treatment operation is carried out at a first temperature to generate a silicide including the main constituent of the first layer and silicon according to a first stoichiometry. In a subsequent step, the additional layer and the protective layer are removed. In another step, a further heat treatment operation is carried out at a temperature greater than the first temperature in order to change the stoichiometry of the previously created silicide.

### FIELD OF THE INVENTION

The present invention refers to a method for producing (manufacturing) an integrated circuit in order to remedy defects or dislocations that may occur during the method.

### PRIOR ART

It is known during the production of integrated circuits to reduce the risks of delamination. To this end, layers are stacked in such a way as to prevent making holes at the interfaces of the stacked layers.

In fact, the U.S. Pat. No. 7,129,169 B2 describes a method for producing an integrated circuit with a stack of layers, with the aim of preventing making holes when stacking the various layers and preventing the risks of delamination. More specifically, it is sought to form a metallic contact on the substrate of an integrated circuit with the formation of a refractory metallic layer on the substrate, which comprises an active and non-active zone, and the formation of a protective layer on the refractory metallic layer. A counter-reaction layer selected from a material such that an opposing directional stress is created between the counter-reaction layer and the cover layer, relative to a directional stress created between the refractory metal layer and the cover layer, is furthermore produced.

FIG. 1 shows the different steps according to a first variant of a method for producing an integrated circuit and, in particular, for producing electrical contacts on a semiconductor substrate 1, which is preferably silicon, of the integrated circuit for electrical connection with external electronic components or by direct contact.

Of course, the representation of the different layers above the substrate is shown in a simplified way only to understand the arrangement of these different layers during the method. The shape of the substrate is also simplified, since such a silicon substrate 1 is usually in the form of a circular wafer. This circular wafer can have a diameter of around 20 cm (8 inches) to 30 cm (12 inches) and a thickness of around 750 μm. However, rectangular silicon wafers are also conceivable.

Initially, at least one first layer 2 of a metallic chemical constituent, which may be cobalt, is disposed on at least one top face of the semiconductor substrate 1 of the integrated circuit to be produced.

Thus, a first preliminary step in the method consists of depositing a first layer 2 on the top face of the silicon semiconductor substrate, for example. This layer may be metallic as soon as it is deposited on the top surface, or it may become conductive by doping carried out from the top surface of the semiconductor substrate. In this first step, a first layer 2 of a metallic constituent, such as cobalt, is deposited. This cobalt layer can be deposited by PVD deposition. Above this first cobalt layer, a protective layer 3 is deposited, for example a layer of titanium nitride (TiN), which acts as a diffusion barrier.

In a second step of the method for producing the integrated circuit, a heat treatment (heating) is carried out, which is the step RTA1. This heat treatment can be of the order of 500° C., but at least 350° C. to modify at least the first layer here from cobalt to cobalt silicide, which can be with different stoichiometries. In this case, the second step of the method consists of producing a cobalt silicide 2′, composed of two cobalt atoms for one silicon atom (Co₂Si). Of course, it is noted that some of the silicon in the substrate is removed to produce this cobalt silicide. During this operation, gaps or even defects or dislocations can occur in the lattice, which can be caused by the protective layer of titanium nitride, whose atomic dimensions are different from those of the first modified layer.

A third step in the method for producing the integrated circuit can of course be carried out, with a further heat treatment similar to the second step, wherein a portion of silicon is further combined or diffused in the first layer in conjunction with the cobalt atoms. In this case, the cobalt silicide 2″ can comprise a cobalt atom and a silicon atom (CoSi). Steps two and three usually take place in a single heat treatment at a temperature above 375° C. and below 550° C.

In a fourth step of the method for producing the integrated circuit, the titanium nitride protective layer is removed by a wet etching operation. Finally, a fifth step RTA2 is carried out with a further heat treatment of up to 750° C. to convert the cobalt silicide 2′″ to a cobalt atom bonded to two silicon atoms (CoSi₂), with some of the silicon diffused in the first cobalt layer.

With this method for producing the integrated circuit according to the prior art, defects and dislocations of the lattice can occur during the method, mainly in the silicon. These defects can then segregate and hence impair the quality of the electrical connection between the semiconductor and the electronic circuit.

FIG. 2 shows the different steps in a second variant of the method for producing the integrated circuit. In this second variant, a silicon oxide (SiO₂) substrate portion 10 is bonded to the silicon substrate in parallel. Otherwise, all the steps described with reference to FIG. 1 are also carried out for the second variant in FIG. 2, but in this case the silicon oxide layer 10 is completely unaffected by all the steps in the method for producing the integrated circuit. This means that the silicon oxide layer 10 retains the same thickness throughout the method for producing the integrated circuit. In the fourth step of the method, however, a portion of cobalt layer 2 must be removed above the silicon oxide layer, in addition to the titanium nitride layer. However, at the end of the fifth step of the method, the heat treatment operation still needs to be carried out like the fifth step described with reference to FIG. 1.

With this method for producing the integrated circuit according to the prior art, defects and dislocations of the lattice are observed, mainly in the silicon. This can adversely affect the quality of the cobalt silicide layer required to provide a good contact layer to make a connection with an external electronic circuit, for example.

### SUMMARY OF THE INVENTION

The aim of the present invention is to produce at least one integrated circuit on a silicon semiconductor substrate with a stack of layers provided to eliminate dislocations or defects in or on the substrate during the method for producing the integrated circuit. Preferably, the present invention relates to the production of an integrated circuit with chemical constituents of different sizes and different behaviours in the different manufacturing steps while preventing having defects or dislocations at the end of the method for producing the integrated circuit.

To this end, the method for producing an integrated circuit comprises the features defined in independent claim 1.

Specific steps for producing the integrated circuit are defined in dependent claims 2 to 10.

An advantage of the method for producing an integrated circuit of the present invention is that, at the end of the manufacturing steps, the integrated circuit is protected from any dislocation or defect.

Advantageously, a first layer of a metallic chemical constituent is initially deposited on one face of the silicon substrate. A protective layer, acting as a diffusion barrier, is then deposited on the first layer. This protective layer consists of a main chemical constituent different from the main chemical constituent of the first layer. An additional layer is furthermore deposited on the protective layer. This additional layer comprises a main chemical constituent different from or equivalent to, or of equivalent size to, the main chemical constituent of the first layer. Preferably, the main chemical constituent of the additional layer is equivalent in size to that of the main chemical constituent of the first layer, and may be, for example, the same main metallic chemical constituent.

Advantageously, siliconisation is performed to ensure good electrical continuity between any contact and the active part. The base component is a silicon wafer or substrate on which a first layer of cobalt can be deposited, for example by the PVD method. On top of this first layer of cobalt, a layer of titanium nitride is deposited, which is very hard and acts as a diffusion barrier.

Advantageously, in the early steps of the method for producing the integrated circuit, an additional layer is furthermore added to the protective layer, which may be a titanium nitride layer, in order to compensate for tension effects between chemical constituents of the preceding layers. This can be referred to as stress balancing between these different layers, so as to prevent the generation of defects or dislocations in said lattice at the end of the integrated circuit production method. This added additional layer may comprise a main chemical constituent different from or equivalent to the main metallic chemical constituent of the first layer. Preferably the main chemical constituent may be cobalt, if the first layer comprises cobalt.

Advantageously, in a subsequent manufacturing step, a layer of cobalt silicide (Co₂Si) according to a first stoichiometry is obtained below the TiN protective layer disposed on this cobalt silicide layer. This protective layer of titanium nitride comprises chemical compounds, in particular titanium, which is of a different size from that of cobalt. Under these conditions, if no additional protection is provided in subsequent steps of the method, the appearance of possible lattice defects or dislocations may occur. For this reason, it is provided to deposit an additional layer on top of the titanium nitride layer from the start of the method, composed of at least one chemical compound of a different or equivalent size to that of the first layer of cobalt initially or cobalt silicide. As mentioned above, the main chemical constituent of the additional layer can be cobalt like the first layer.

At the end of the method for producing the integrated circuit, the additional layer and the titanium nitride layer are removed, along with the cobalt layer if still present. All that ultimately remains is the cobalt silicide layer produced on the silicon substrate according to a second stoichiometry. Thanks to the additional layer added during the manufacturing method, it is observed at the end of the manufacturing method that no defects or dislocations have occurred. Furthermore, since the additional layer and the titanium nitride layer have been removed, it is not possible to deduce how the defect- and dislocation-free integrated circuit was produced.

### BRIEF DESCRIPTION OF THE DRAWINGS

The aims, advantages and features of the method for producing an integrated circuit to remedy defects or dislocations will become more apparent in the following description, in a non-limiting manner, with reference to the drawings wherein:

FIG. 1 shows in simplified form the different steps of a first variant of the method for producing an integrated circuit according to the prior art,

FIG. 2 shows in simplified form the different steps of a second variant of the method for producing an integrated circuit according to the prior art, based on similar production steps to those described for FIG. 1,

FIG. 3 shows in simplified form the different steps of a first variant of the method for producing an integrated circuit according to the present invention, which comprises an additional layer disposed on a protective layer with implementation steps described in part with reference to FIG. 1 to remedy dislocations or defects that may occur during the method,

FIG. 4 shows in simplified form the different steps of a second variant of the method for producing an integrated circuit according to the present invention, which comprises an additional layer disposed on a protective layer with implementation steps described in part with reference to FIG. 2 to remedy dislocations or defects that may occur during the method,

FIG. 5 shows a table comparing the method for producing an integrated circuit according to the prior art with the method for producing an integrated circuit according to the present invention, for which an additional layer is added to a protective layer from the start of the production method, and

FIG. 6 shows a table of the structure of the first layer during the three essential steps of the method for producing an integrated circuit according to the present invention, mainly concerning the first cobalt silicide layer with different stoichiometries.

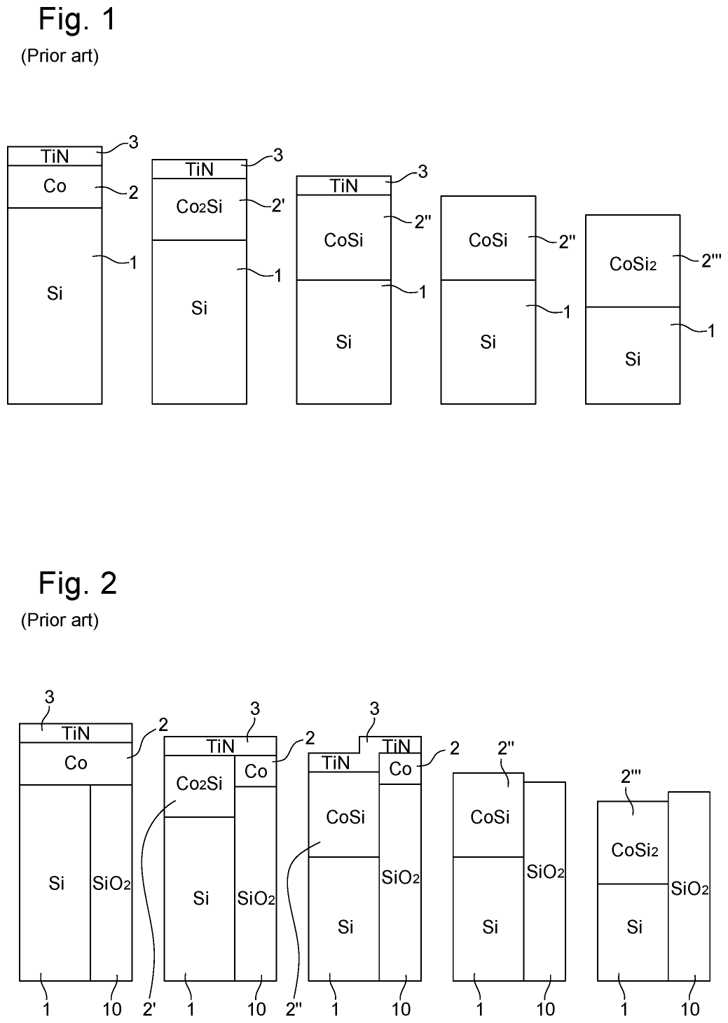

### DETAILED DESCRIPTION OF THE INVENTION

In the following description, the integrated circuit is normally produced on a silicon semiconductor base or wafer or substrate. Preferably, a method is described for producing or manufacturing the integrated circuit in such a way as, for example, to produce electrical contact layers or pads for bonding external electronic components or components disposed in direct contact with the integrated circuit produced.

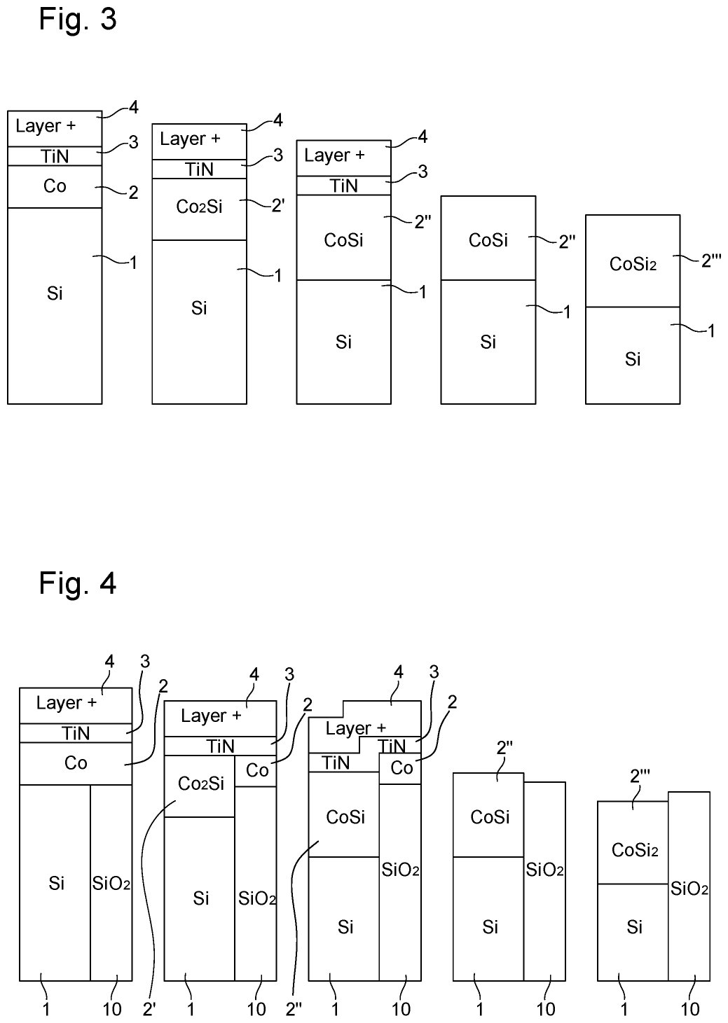

FIG. 3 shows the different steps according to a first variant of a method for producing an integrated circuit without defects or dislocations at the end of the method. It can be sought with this method to produce or manufacture at least electrical contacts on the silicon semiconductor substrate 1 of the integrated circuit for electrical connection to external electronic components or by direct contact. However, it may also be envisaged to produce electrically conductive portions for connecting different electronic components produced on or in the integrated circuit, or other parts of the integrated circuit.

Of course, the representation of the different layers above the silicon substrate 1 is shown in a simplified way only to understand the arrangement of these different layers during the method as explained in paragraph [0005] above.

Initially, in a preliminary step or first step of the method, at least a first layer 2 of a metallic chemical constituent is deposited on at least one top face of the semiconductor substrate 1 of the integrated circuit to be produced. The constituent may be cobalt, which is a good electrical conductor, or other metallic chemical constituents such as titanium or nickel. This first metallic layer 2 can also become conductive by doping carried out from the top surface of the silicon semiconductor substrate 1.

This first metallic layer 2, such as cobalt, can be deposited by PVD. Above this first cobalt layer 2, a protective layer 3 is deposited, which acts as a diffusion barrier. This can be a layer of titanium nitride (TiN), for example. Furthermore, according to the invention, an additional layer 4 is further deposited on the protective layer 3 to compensate for various stresses during the steps of the method. This additional layer 4 consists of a main chemical constituent that is different from, equivalent to or of equivalent size to the main metallic chemical constituent of the first layer 2. In the case of a first layer composed of cobalt, the additional layer 4 may also comprise cobalt as the main chemical constituent. It is above all with this configuration that it is possible to arrive at the end of the method without defects or dislocations of the integrated circuit lattice.

In a second step of method for producing the integrated circuit, a heat treatment (heating) operation is carried out, which is a defined step RTA1. This heat treatment operation is carried out at a defined temperature to generate a silicide 2′ consisting of the main constituent of the first layer 2 and silicon 1 according to a first stoichiometry. If the first layer is composed of cobalt, this first heat treatment operation makes it possible to obtain cobalt silicide 2′ according to a first stoichiometry, i.e. with two cobalt atoms bonded to one silicon atom (Co₂Si).

This heat treatment operation can be of the order of 500° C., but at least 350° C. to modify at least the first layer here of cobalt from cobalt to cobalt silicide, which can be with different stoichiometries. Of course, it is noted that some of the silicon in the substrate is removed to produce this cobalt silicide.

Of course, a third step of the method for producing the integrated circuit may optionally be carried out, with a further heat treatment at a temperature equivalent to, different from or greater than that of the second step of the method. As in the second step, a further silicide is produced, consisting of the main constituent of the first layer 2 and silicon 1, or a portion of silicon is further combined or diffused in the first layer in conjunction with the cobalt atoms. In this case, if the main constituent of the first layer 2 is cobalt, this will consist of cobalt silicide 2″, which may comprise a cobalt atom and a silicon atom (CoSi) according to a second stoichiometry.

It should be noted that Cobalt silicides 2′ and 2″ are generally created consecutively during the first siliconisation method RTA1 at a temperature >400° C. and <550° C., combining the second and third steps.

In a fourth step of the method for producing the integrated circuit, or in a subsequent step of the second step, the protective layer 3 and the additional layer 4 are removed by a wet etching operation. Finally, in a fifth or final step of the method defined as RTA2, a further heat treatment operation is carried out at a higher temperature than the first temperature in order to change the stoichiometry of the previously created silicide, i.e. silicide consisting of the main constituent of the first layer 2 and silicon 1. In the case of cobalt, this will consist of cobalt silicide 2′″ with one cobalt atom bonded to two silicon atoms (CoSi₂), if the third step of the method has been carried out and according to a third stoichiometry.

In the case of cobalt, the first temperature of heat treatment RTA1 to produce cobalt silicide is at least 400° C., and may be as high as 500° C. to create the silicide 2″. The temperature of the last siliconisation step of the last heat treatment RTA2 can be set at 550° C., and can even go up to 750° C. Siliconisation can also be carried out on other chemical metal constituents, such as nickel or titanium, or any other metal material capable of being siliconised. In this case, the siliconisation temperatures should be adapted.

After removing the additional layer 4 and the titanium nitride protective layer by wet etching, all that remains is the final step in the method for producing the integrated circuit, with the above-mentioned heat treatment at a temperature greater than 550° C. The cobalt silicide is according to a third stoichiometry if the method includes all the steps described above. At the end of the method, as the additional layer and the titanium nitride layer have been removed by wet etching, it can be noted that the way to make the integrated circuit defect-free and dislocation-free has been rendered invisible, as it is not possible to know which method has been used to prevent this dislocation defect problem.

FIG. 4 shows the different steps according to a second variant of the method for producing an integrated circuit according to the present invention. In this second variant, a silicon oxide (SiO₂) substrate portion 10 is bonded to the silicon substrate in parallel. Otherwise, all the steps described with reference to FIG. 3 are also carried out for the second variant in FIG. 4. However, the silicon oxide layer 10 is completely unaffected by all the steps in the method for producing the integrated circuit. This means that the silicon oxide layer 10 retains the same thickness throughout the method for producing the integrated circuit. In the fourth step of the method, however, a portion of the first cobalt layer 2 must furthermore be removed above the silicon oxide layer, in addition to the additional layer 4 and the titanium nitride protective layer 3. At the end of the fifth or final step of the method, the heat treatment operation still needs to be carried out like the fifth step described with reference to FIG. 3.

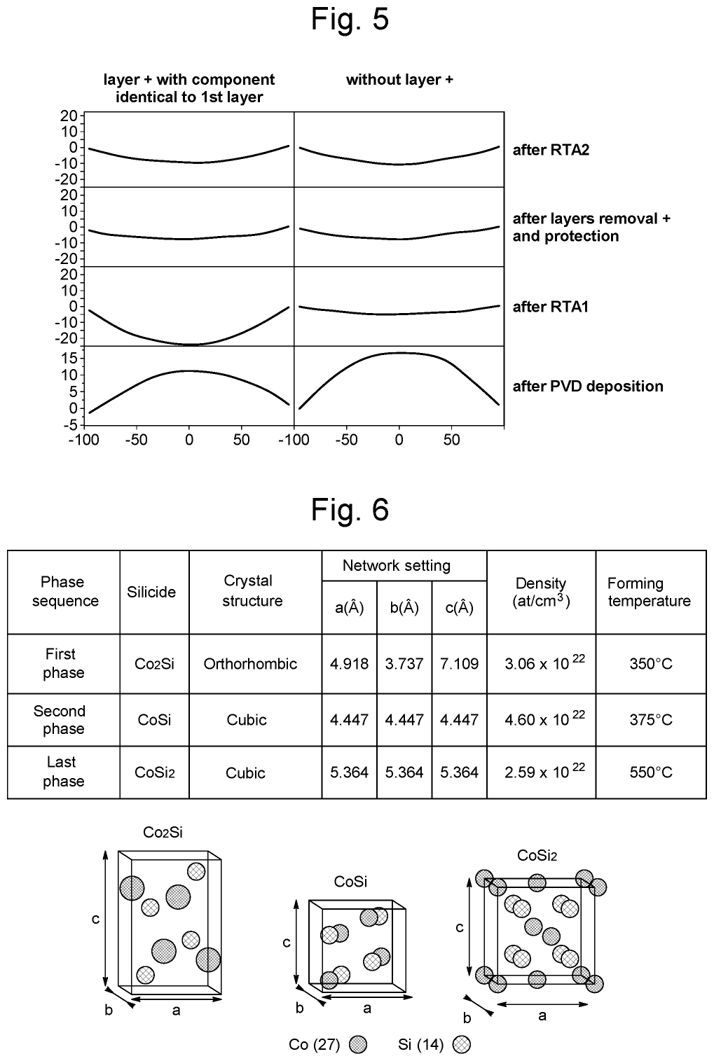

FIG. 5 shows only a comparison between the method for producing the integrated circuit according to the present invention on the left-hand side and according to the prior art on the right-hand side of the table. It is shown mainly in the second and/or third step of the method during the first heat treatment with siliconisation of the first cobalt and silicon layer, that compression is greater thanks to the protective layer on which the additional layer is disposed acting to prevent the generation of defects or dislocations during the integrated circuit manufacturing method.

Finally, FIG. 6 merely shows a table of the different steps in the method for producing the integrated circuit according to the present invention, and mainly the crystal structure from the second to the fifth or final step in the method for producing the integrated circuit. There is no need to add any further information, as the information presented in FIGS. 5 and 6 is sufficiently clear to understand the advantage of the present invention.

Several variants of the method for producing the defect-free or dislocation-free integrated circuit can be envisaged without leaving the scope of the claims presented.

1. A method for producing an integrated circuit free from defects or dislocations at the end of the method, for which a first layer of a metallic chemical constituent is initially deposited on at least one silicon semiconductor substrate, and a protective layer including a main chemical constituent different from the main chemical constituent of the first layer is deposited on this first layer, wherein an additional layer comprising a main chemical constituent different from or equivalent to or of equivalent size to the main chemical constituent of the first layer is deposited on the protective layer, wherein, in a subsequent step of the method, a heat treatment operation is carried out at a first defined temperature in order to generate a silicide including the main constituent of the first layer and silicon according to a first stoichiometry, wherein, in a subsequent step of the method, the additional layer and the protective layer are removed by a wet etching operation, and in a final step of the method, a further heat treatment operation is carried out at a second defined temperature higher than the first defined temperature in order to change the stoichiometry of the previously created silicide.

2. The method for producing an integrated circuit according to claim 1, wherein the first metallic chemical layer, which comprises cobalt or nickel or titanium, is deposited on one face of the silicon substrate by a PVD method.

3. The method for producing an integrated circuit according to claim 1, wherein that wherein the first metallic chemical layer, which is composed of cobalt, is deposited on one face of the silicon substrate by a PVD method.

4. The method for producing an integrated circuit according to claim 1, wherein a protective layer, which is adapted to act as a diffusion barrier, is deposited.

5. The method for producing an integrated circuit according to claim 4, wherein the protective layer, which is composed of titanium nitride, is deposited on the first layer, which is composed of cobalt.

6. The method for producing an integrated circuit according to claim 1, wherein the additional layer comprises a main chemical constituent equivalent to the main chemical constituent of the first layer.

7. The method for producing an integrated circuit according to claim 1, wherein, in a first step of the method, a first layer of a metallic chemical constituent, which is cobalt, is deposited on one face of the silicon substrate, in that the protective layer of titanium nitride is deposited on the first layer, and wherein the additional layer is deposited on the protective layer.

8. The method for producing an integrated circuit according to claim 7, wherein the additional layer, comprising cobalt, is deposited on the protective layer.

9. The method for producing an integrated circuit according to claim 7, wherein, in a second step of the method, a first heat treatment operation is carried out at a first defined temperature in order to generate a cobalt silicide according to a first stoichiometry with two cobalt atoms and one silicon atom, in that, in a third step of the method, a second heat treatment operation is carried out at a temperature equivalent to or greater than the first temperature to generate a cobalt silicide according to a second stoichiometry with one cobalt atom and one silicon atom, in that, in a fourth step of the method, the additional layer, the protective layer and any remaining first layer are removed by wet etching, and wherein, in a final step of the method, a third heat treatment is carried out at a temperature greater than the previous heat treatment temperatures to generate a cobalt silicide according to a third stoichiometry with one cobalt atom and two silicon atoms.

10. The method for producing an integrated circuit according to claim 9, wherein the first heat treatment operation is carried out at a temperature of the order of 350° C., in that the second heat treatment operation is carried out at a temperature of the order of 375° C., and wherein the third heat treatment operation is carried out at a temperature of the order of 550° C.
